(19) United States
(12) Patent Application Publication
(10) Pub. No.: US 2019/0312122 A1
(43) Pub. Date: Oct. 10, 2019

(54) ELECTRONIC COMPONENT, METHOD FOR MANUFACTURING ELECTRONIC COMPONENT, AND ELECTRONIC DEVICE

(71) Applicant: FUJITSU LIMITED, Kawasaki-shi (JP)

(72) Inventors: Masaru Morita, Isehara (JP); Yoshihiro Nakata, Atsugi (JP)

(73) Assignee: FUJITSU LIMITED, Kawasaki-shi, Kanagawa (JP)

(21) Appl. No.: 16/451,477

(22) Filed: Jun. 25, 2019

Related U.S. Application Data
(63) Continuation of application No. PCT/JP2018/000117, filed on Jan. 5, 2018.

(30) Foreign Application Priority Data
Jan. 19, 2017 (JP) 2017-007176

(51) Int. Cl. H01L 29/45; H01L 21/283; H01L 23/498; H05K 3/24; H05K 1/09

(52) U.S. Cl. CPC H01L 29/45; H01L 21/283; H01L 23/49866; H01L 2924/1517; H05K 1/09; H01L 2224/16225; H05K 3/24

(57) ABSTRACT

An electronic component includes: a conductor portion containing a first element; a compound layer disposed around the conductor portion and containing a second element and a third element which are different from the first element; and an isolation layer, disposed between the conductor portion and the compound layer and containing a fourth element which is different from the first element, the second element, and the third element, to isolate the first element in the conductor portion from the second element and the third element outside the conductor portion.

### CROSS-REFERENCE TO RELATED APPLICATION

This application is a continuation application of International Application PCT/JP2018/000117 filed on Jan. 5, 2018 and designated the U.S., the entire contents of which are incorporated herein by reference. The International Application PCT/JP2018/000117 is based upon and claims the benefit of priority of the prior Japanese Patent Application No. 2017-007176, filed on Jan. 19, 2017, the entire contents of which are incorporated herein by reference.

### FIELD

The embodiments discussed herein are related to an electronic component, a method for manufacturing an electronic component, and an electronic device.

### BACKGROUND

The embodiments discussed herein are related to an electronic component such as a semiconductor device or a circuit board.

Japanese Laid-open Patent Publication No. 2015-82534 and Japanese Laid-open Patent Publication No. 2009-4454 are disclosed as related art.

### SUMMARY

According to an aspect of the embodiments, an electronic component includes: a conductor portion containing a first element; a compound layer disposed around the conductor portion and containing a second element and a third element which are different from the first element; and an isolation layer, disposed between the conductor portion and the compound layer and containing a fourth element which is different from the first element, the second element, and the third element, to isolate the first element in the conductor portion from the second element and the third element outside the conductor portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are views for explaining an example of a conductor portion of an electronic component;

FIGS. 2A and 2B are views for explaining another example of the conductor portion of the electronic component;

FIG. 3 is a view (No. 1) illustrating an example of an electronic component according to a first embodiment;

FIG. 4 is a view (No. 2) illustrating an example of the electronic component according to the first embodiment;

FIGS. 5A to 5C are views (No. 1) illustrating an example of a method for forming an electronic component according to the first embodiment;

FIGS. 6A to 6C are views (No. 2) illustrating an example of the method for forming an electronic component according to the first embodiment;

FIGS. 7A to 7C are views (No. 3) illustrating an example of the method for forming an electronic component according to the first embodiment;

FIGS. 8A and 8B are views (No. 4) illustrating an example of the method for forming an electronic component according to the first embodiment;

FIGS. 9A to 9C are views (No. 1) illustrating an example of a method for forming an electronic component according to a second embodiment;

FIGS. 10A and 10B are views (No. 2) illustrating an example of the method for forming an electronic component according to the second embodiment;

FIGS. 11A and 11B are views (No. 3) illustrating an example of the method for forming an electronic component according to the second embodiment;

FIGS. 12A and 12B are views (No. 4) illustrating an example of the method for forming an electronic component according to the second embodiment;

FIG. 13 is a view (No. 1) illustrating an example of an electronic component according to a third embodiment;

FIG. 14 is a view (No. 2) illustrating an example of the electronic component according to the third embodiment;

FIG. 15 is a view illustrating an example of a circuit board according to a fourth embodiment;

FIGS. 16A and 16B are views illustrating an example of a semiconductor package according to the fourth embodiment;

FIG. 17 is a view illustrating another example of the semiconductor package according to the fourth embodiment;

FIG. 18 is a view illustrating an example of a semiconductor chip according to the fourth embodiment;

FIG. 19 is a view illustrating an example of an electronic device according to a fifth embodiment; and

FIG. 20 is an explanatory view of an electronic apparatus according to a sixth embodiment.

### DESCRIPTION OF EMBODIMENTS

For example, a connection terminal in which an electroless nickel plating film and an electroless palladium plating film are sequentially disposed on terminal-shaped copper, and a connection terminal in which a substitution gold plating film is further disposed on the electroless palladium plating film may be provided. In addition, an electrode structure may be provided in which a nickel layer is disposed on a copper electrode, and a nickel tin alloy is disposed on the nickel layer.

When another layer is laminated on a conductor portion of an electronic component as described above, an element contained in the conductor portion reacts with an element contained in another layer laminated on the conductor portion to form a compound. As a result, the size of the conductor portion may be reduced from its original size, and the resistance of the conductor portion may be increased. Such an increase in the resistance of the conductor portion may lead to a decrease in performance and reliability of the electronic component and an electronic device using the electronic component.

First, an example of a conductor portion of an electronic component will be described.

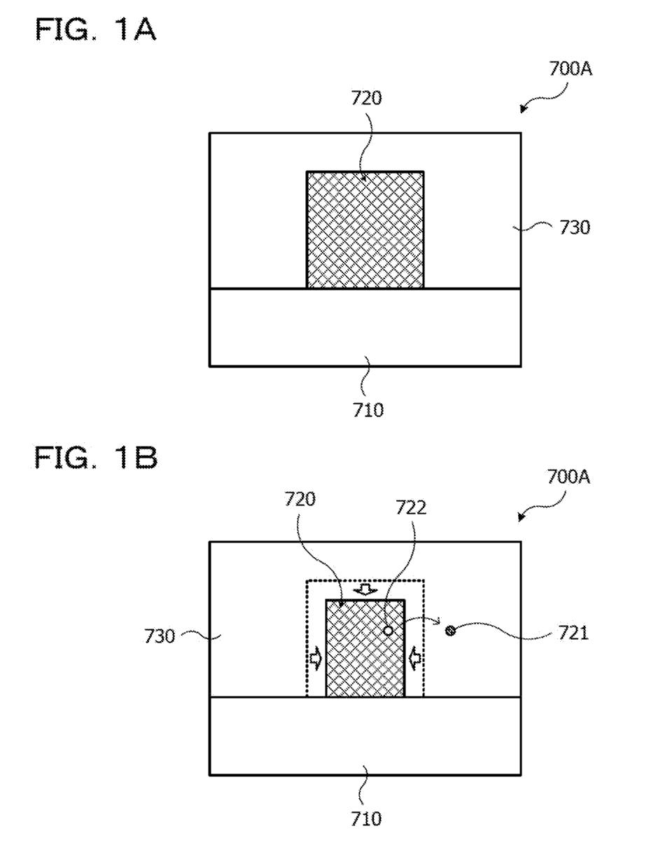

FIGS. 1A and 1B are views for explaining an example of the conductor portion of the electronic component. FIGS. 1A and 1B each schematically illustrate a cross-section of a main part of an example of the conductor portion.

An electronic component 700A illustrated in FIG. 1A includes a substrate 710 and a conductor portion 720 disposed thereon. The substrate 710 is a semiconductor substrate such as silicon (Si), a resin substrate such as polyimide, an interlayer insulating film made of an organic material or an inorganic material, or the like. The conductor portion 720 is wiring or an electrode. The conductor portion 720 is made of copper (Cu) or a metal material containing Cu. On the substrate 710 having the conductor portion 720 disposed thereon, an insulating layer 730 is disposed so as to cover the conductor portion 720. For the insulating layer 730, for example, a resin material such as polyimide or epoxy is used.

In addition to the case where a side surface and an upper surface of the conductor portion 720 are covered with the insulating layer 730 as illustrated in FIG. 1A, the conductor portion 720 may be covered with the insulating layer 730 such that the upper surface thereof is exposed for external connection or connection with another conductor portion.

As in the electronic component 700A illustrated in FIG. 1A, when a structure in which the conductor portion 720 (part or whole thereof) on the substrate 710 is covered with the insulating layer 730 is adopted, the following may occur. For example, when heat is applied to the conductor portion 720 during manufacturing or operation of the electronic component 700A, Cu contained in the conductor portion 720 may diffuse into the insulating layer 730. In FIG. 1B, Cu diffused into the insulating layer 730 is schematically illustrated by Cu 721. When Cu of the conductor portion 720 diffuses into the insulating layer 730 in this manner, as illustrated in FIG. 1B, a void 722 may be generated in the conductor portion 720, or the size of the conductor portion 720 may be reduced from its original size (illustrated by the dotted line in FIG. 1B), and the resistance of the conductor portion 720 may be thereby increased. Such diffusion of Cu of the conductor portion 720 and an increase in resistance due to the diffusion may occur similarly due to heat during manufacturing (assembly) or operation of an electronic device or an electronic apparatus using the electronic component 700A including the conductor portion 720.

As a technique for suppressing the diffusion of Cu of the conductor portion 720 which may cause an increase in resistance, there is a technique for covering the conductor portion 720 with a cap layer.

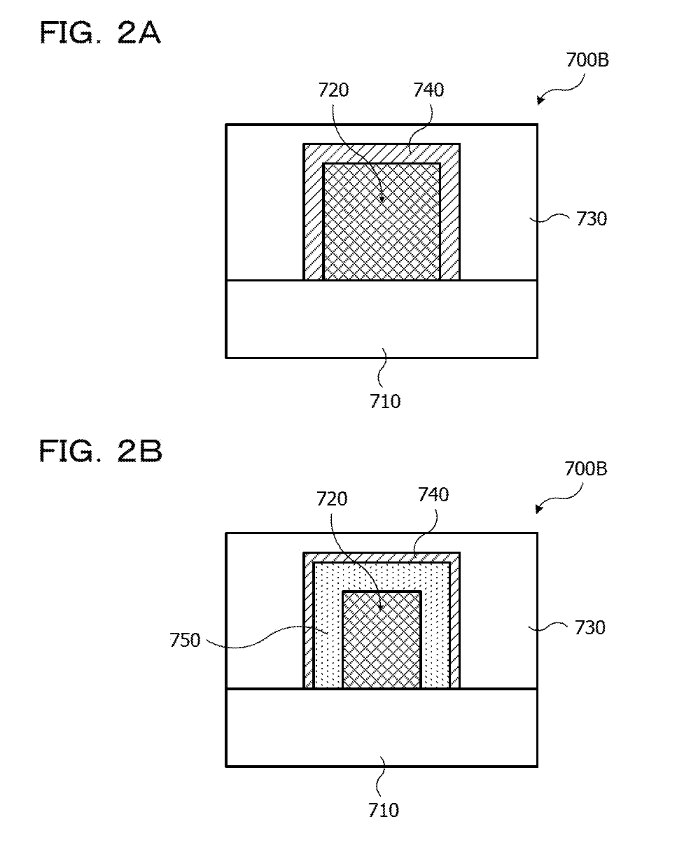

FIGS. 2A and 2B are views for explaining another example of the conductor portion of the electronic component. FIGS. 2A and 2B each schematically illustrate a cross-section of a main part of another example of the conductor portion.

In an electronic component 700B illustrated in FIG. 2A, a cap layer 740 (metal cap) is disposed so as to cover the conductor portion 720 on the substrate 710, and the periphery thereof is covered with the insulating layer 730.

In addition to the case where a side surface and an upper surface of a laminate of the conductor portion 720 and the cap layer 740 are covered with the insulating layer 730 as illustrated in FIG. 2A, the laminate may be covered with the insulating layer 730 such that the upper surface of the laminate or an upper surface of an inner layer thereof is exposed for external connection or connection with another conductor portion.

For the cap layer 740, for example, a material that can be formed by electroless plating on a surface of the conductor portion 720 disposed on the substrate 710 is used. Examples of such a material include a metal material such as nickel (Ni), a compound of Ni and phosphorus (P) (Ni—P), or a compound of cobalt (Co) and tungsten (W) (Co—W). Among these materials, Ni—P is widely adopted as the material of the cap layer 740 because electroless Ni—P plating is relatively easy to manage a solution, is low in cost, and can form the cap layer 740 with good uniformity. For the purpose of suppressing diffusion of Cu contained in the conductor portion 720 into the insulating layer 730, the conductor portion 720 is covered with, for example, such a cap layer 740 formed of Ni—P.

However, in the electronic component 700B using Ni—P for the cap layer 740, corrosion of the conductor portion 720 in a process of forming Ni—P by electroless plating or a reaction (alloying) between Ni in the formed Ni—P and Cu of the conductor portion 720 may occur.

For example, in the case of forming the cap layer 740 by electroless Ni—P plating, Ni—P is not formed on a surface of the conductor portion 720 simply by immersing the substrate 710 on which the conductor portion 720 is formed using Cu in an electroless Ni—P plating solution. Before immersion in an electroless Ni—P plating solution, the substrate 710 on which the conductor portion 720 is formed is first immersed in an electroless palladium (Pd) plating solution, and Pd as a nucleus of Ni—P plating is formed on a surface of the conductor portion 720 (Pd treatment). By immersing the substrate 710 in which a nucleus of Pd is formed on the surface of the conductor portion 720 by such a Pd treatment in the electroless Ni—P plating solution, Ni—P grows with Pd as a nucleus to form the cap layer 740 of Ni—P on the surface of the conductor portion 720.

The Pd treatment is a substitution reaction with Cu of the conductor portion 720, is therefore a treatment of forming Pd while melting Cu on the surface of the conductor portion 720, and is, so to speak, a treatment that proceeds while corroding the surface of the conductor portion 720. Corrosion of the surface of the conductor portion 720 can be suppressed by shortening time of the Pd treatment. However, Pd as a nucleus is not sufficiently formed on the surface of the conductor portion 720. Therefore, in the subsequent electroless Ni—P plating, the good Ni—P cap layer 740 is not necessarily formed.

In addition, Ni contained in Ni—P of the formed cap layer 740 and Cu contained in the conductor portion 720 may diffuse due to heat during manufacturing or operation of the electronic component 700B to form an alloy (Cu—Ni) of Cu and Ni. As a result, a Cu—Ni alloy 750 as illustrated in FIG. 2B may be formed between the cap layer 740 and the conductor portion 720. When Cu of the conductor portion 720 is consumed for formation of such an alloy 750, the size of the conductor portion 720 may be reduced from its original size. This may increase the resistance of the conductor portion 720. By changing the material of the cap layer 740 from a material using Ni to another metal material that is less likely to cause a reaction with Cu of the conductor portion 720, formation of a compound with Cu and an increase in resistance due to the formation of the compound can also be suppressed. However, there are difficulty in management of a solution, an increase in cost, difficulty in uniformly forming the cap layer 740, and the like.

An influence of corrosion of the conductor portion 720 as described above and an increase in resistance of the conductor portion 720 due to formation of the alloy 750 on performance and reliability of the electronic component 700B, an electronic device using the electronic component 700B, or the like tends to be more significant as the conductor portion 720 becomes finer.

In view of the above-described points, a configuration as exemplified below as an embodiment is adopted here to suppress an increase in resistance of a conductor portion disposed in an electronic component.

First, a first embodiment will be described.

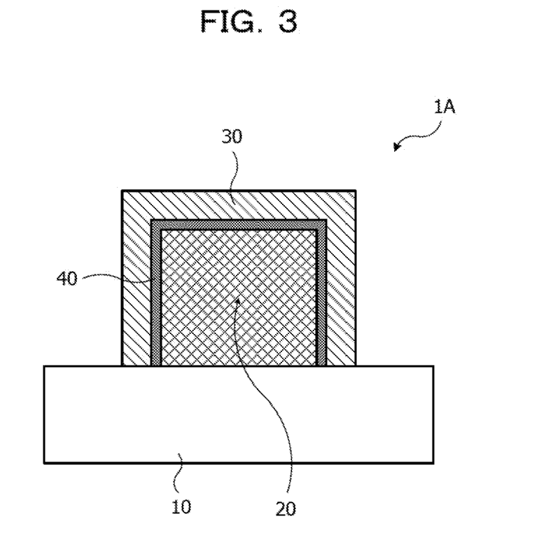

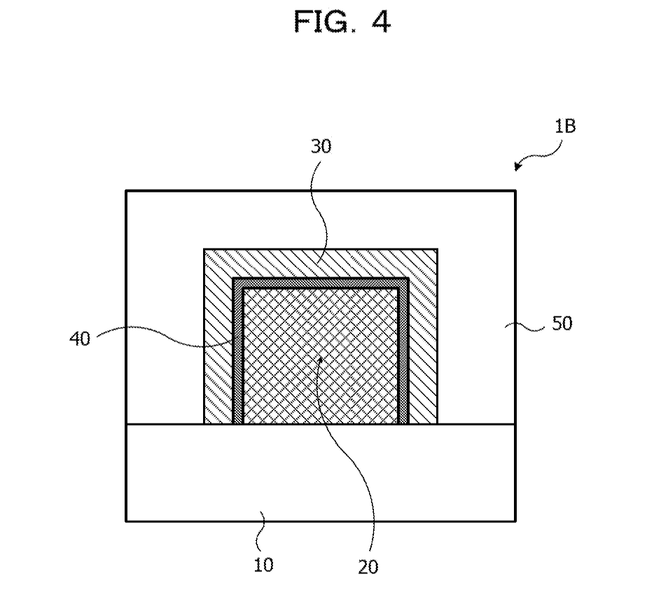

FIGS. 3 and 4 are views illustrating an example of an electronic component according to the first embodiment. FIG. 3 schematically illustrates a cross-section of a main part of a first example of the electronic component according to the first embodiment. FIG. 4 schematically illustrates a cross-section of a main part of a second example of the electronic component according to the first embodiment.

For example, an electronic component 1A illustrated in FIG. 3 includes a substrate 10, a conductor portion 20 disposed thereon, a compound layer 30 disposed around the conductor portion 20, and an isolation layer 40 disposed between the conductor portion 20 and the compound layer 30.

As the substrate 10, various substrates such as a semiconductor substrate of Si or the like, a resin substrate of polyimide or the like, an interlayer insulating film made of an organic material or an inorganic material, a glass substrate, and a ceramic substrate are used.

The conductor portion 20 is wiring or an electrode. For the conductor portion 20, for example, Cu or a metal material containing Cu is used. The conductor portion 20 has a single-layer structure or a laminated structure of a plurality of layers (for example, a laminated structure of a seed layer and a plating layer stacked thereon during electrolytic plating).

The compound layer 30 disposed around the conductor portion 20 on the substrate 10 is, for example, a layer of a compound (Ni—Sn) containing Ni and tin (Sn). The compound layer 30 is, for example, a layer of an intermetallic compound stably present against heat during manufacturing and operation of the electronic component 1A, such as Ni₃Sn or Ni₃Sn₂.

The isolation layer 40 disposed between the compound layer 30 and the conductor portion 20 contains, for example, boron (B). The isolation layer 40 is a layer of B alone or, for example, a layer of a compound (B—P) containing B and P, a layer of a compound (B—W) containing B and W, a layer of a compound (B—Co) containing B and Co, a layer of a compound (B—P—W) containing B, P, and W, or a layer of a compound (B—P—Co) containing B, P, and Co. The isolation layer 40 isolates Cu contained in the conductor portion 20 from Ni and Sn contained in the compound layer 30.

As described later, the isolation layer 40 contains B or the like segregated along with formation of the compound layer 30 of Ni—Sn by a reaction between a metal layer containing Ni, B, or the like formed on a surface of the conductor portion 20 and a metal layer containing Sn further formed on a surface thereof.

On the substrate 10 in which the compound layer 30 is formed around the conductor portion 20 through the isolation layer 40, for example, as in the electronic component 1B illustrated in FIG. 4, an insulating layer 50 may be disposed so as to cover the laminate of the conductor portion 20, the isolation layer 40, and the compound layer 30. For the insulating layer 50, in addition to a resin material such as polyimide, polybenzoxazole, or epoxy, various organic or inorganic insulating materials are used.

In addition to the case where a side surface and an upper surface of the laminate of the conductor portion 20, the isolation layer 40, and the compound layer 30 are covered with the insulating layer 50 as illustrated in FIG. 4, the laminate may be covered with the insulating layer 50 such that the upper surface of the laminate or an upper surface of an inner layer thereof is exposed for external connection or connection with another conductor portion.

As described above, in the electronic components 1A and 1B, a surface of the conductor portion 20 on the substrate 10 is covered with the isolation layer 40, and the isolation layer 40 is covered with the compound layer 30.

When the conductor portion 20 contains Cu, the isolation layer 40 contains B, and the compound layer 30 contains Ni and Sn, Ni of the compound layer 30 forms a stable intermetallic compound with Sn. Meanwhile, B of the isolation layer 40 does not form or hardly forms a compound with Cu of the conductor portion 20 or Sn and Ni of the compound layer 30.

In the electronic components 1A and 1B, a reaction between B contained in the isolation layer 40 and Cu contained in the conductor portion 20 inside the isolation layer 40 is suppressed, and a reaction between B contained in the isolation layer 40 and Sn contained in the compound layer 30 outside the isolation layer 40 is suppressed. Ni contained in the compound layer 30 outside the isolation layer 40 forms a stable intermetallic compound with Sn, and B or the like is segregated along with the formation to form the isolation layer 40. The isolation layer 40 containing B isolates Cu contained in the conductor portion 20 from Ni and Sn contained in the compound layer 30, and exhibits a barrier function to suppress diffusion thereof and a reaction therebetween.

In the electronic components 1A and 1B, the barrier function of the isolation layer 40 suppresses a reaction between Cu contained in the conductor portion 20 and Ni and Sn contained in the compound layer 30 outside the conductor portion 20. By suppressing the reaction between Cu in the conductor portion 20 and an element outside the conductor portion 20 in this manner, reduction in the size of the conductor portion 20 from its original size and an increase in the resistance of the conductor portion 20 due to the reduction in the size are suppressed.

In the electronic component 1B in which the insulating layer 50 is disposed around the compound layer 30, the compound layer 30 is formed of a stable intermetallic compound, and diffusion of Ni and Sn contained in the compound layer 30 into the insulating layer 50 is thereby suppressed.

In the electronic components 1A and 1B each including the conductor portion 20, the isolation layer 40, and the compound layer 30 as described above, a reaction of the conductor portion 20 with an element present at an outside thereof, reduction in size due to the reaction, and an increase in resistance due to the reduction in size are suppressed. As a result, the electronic components 1A and 1B having excellent performance and reliability are achieved.

The combination of elements contained in the conductor portion 20, the isolation layer 40, and the compound layer 30 of the electronic components 1A and 1B is not limited to the above example (Cu, B, Ni, and Sn). The combination of elements is not limited as long as the conductor portion 20 is used as wiring or an electrode, the compound layer 30 is formed as a stable compound, and the isolation layer 40 is present between the conductor portion 20 and the compound layer 30 and suppresses diffusion and a reaction of elements contained therein.

Subsequently, a method for forming the electronic components 1A and 1B having the above-described configurations will be described.

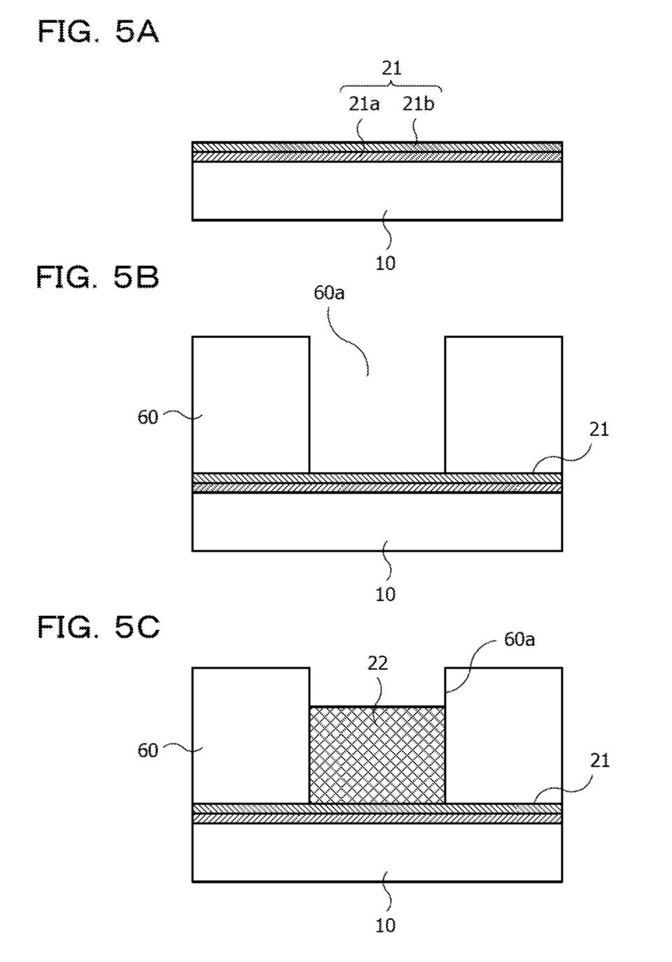

FIGS. 5A to 8B are views illustrating an example of a method for forming an electronic component according to the first embodiment. FIGS. 5A to 5C, FIGS. 6A to 6C, FIGS. 7A to 7C, and FIGS. 8A and 8B each schematically illustrate a cross-section of a main part in each step of an example of the method for forming an electronic component according to the first embodiment.

As illustrated in FIG. 5A, a seed layer 21 is formed on the substrate 10. For example, a laminated film of a titanium (Ti) film 21a and a Cu film 21b is formed as the seed layer 21.

After the formation of the seed layer 21, as illustrated in FIG. 5B, a resist 60 having an opening 60a is formed in a region where the conductor portion 20 described later is to be formed thereon.

After the formation of the resist 60, as illustrated in FIG. 5C, a conductor layer 22 is formed on the seed layer 21 in the opening 60a. For example, the conductor layer 22 is formed by electrolytic Cu plating using the seed layer 21 as a feeding layer.

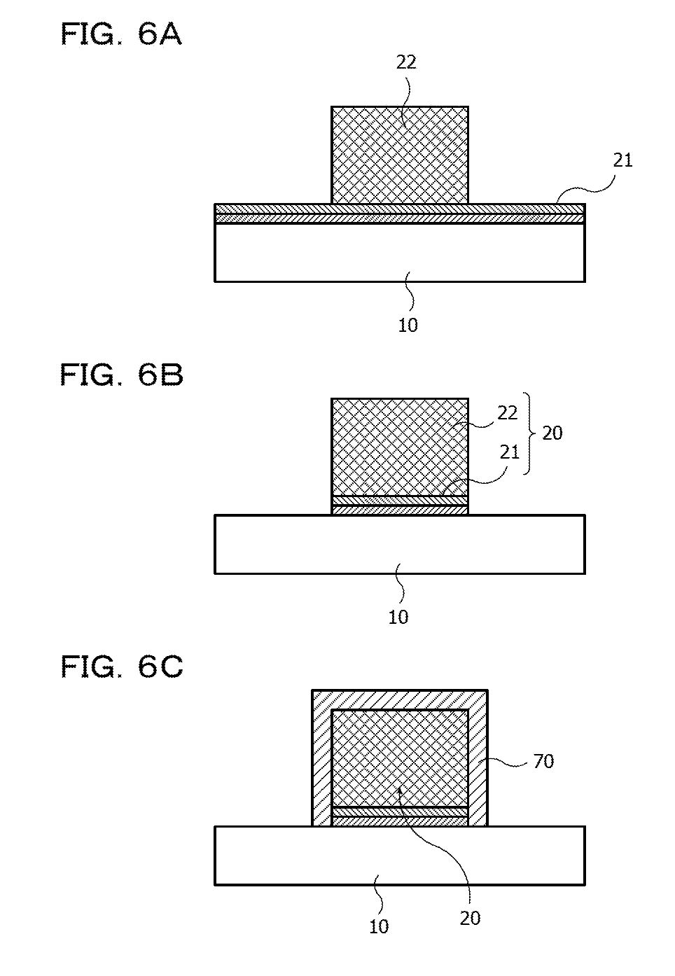

After the formation of the conductor layer 22, as illustrated in FIG. 6A, the resist 60 is peeled off.

After peeling of the resist 60, the seed layer 21 exposed thereby is removed by etching as illustrated in FIG. 6B. As a result, the conductor portion 20 including the seed layer 21 and the conductor layer 22 formed thereon as illustrated in FIG. 6B is formed.

After the formation of the conductor portion 20, as illustrated in FIG. 6C, a metal layer 70 is formed on a surface thereof. For example, as the metal layer 70, a metal layer containing Ni and B is formed. Such a metal layer 70 is formed by, for example, electroless Ni—B plating, electroless Ni—B—P plating, electroless Ni—B—W plating, electroless Ni—B—Co plating, electroless Ni—B—P—W plating, or electroless Ni—B—P—Co plating. Each of these electroless plating solutions used to form the metal layer 70 containing Ni and B contains dimethylamine borane (DMAB) having high activity as a component. Therefore, using these electroless plating solutions, the metal layer 70 can be formed directly on a surface of the conductor portion 20 without performing such a Pd treatment as described above. As a result, corrosion of the conductor portion 20 at the time of electroless plating is suppressed.

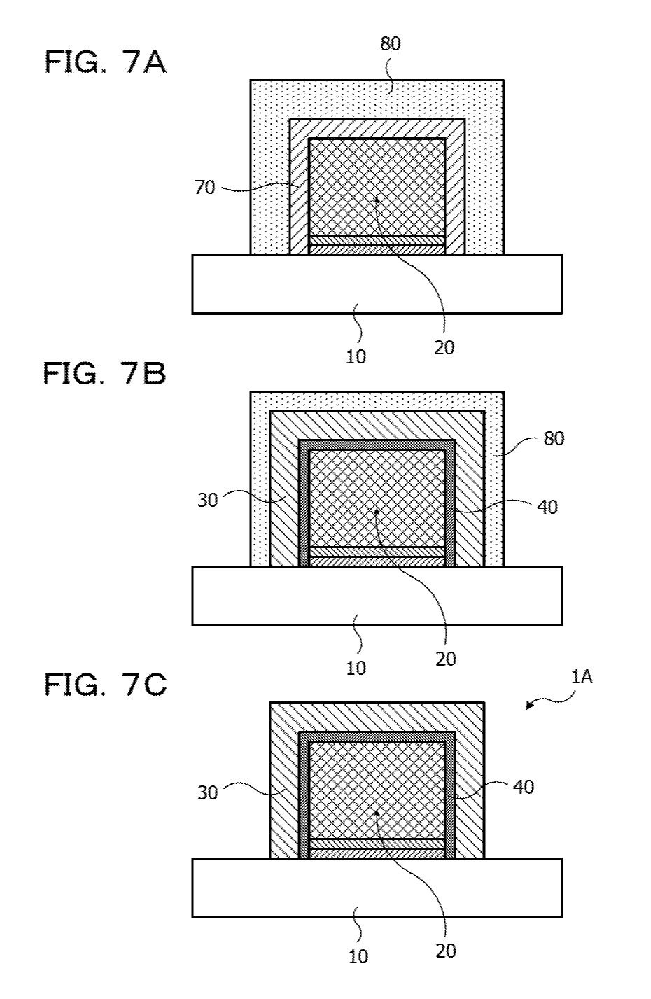

After the formation of the metal layer 70, as illustrated in FIG. 7A, a metal layer 80 is further formed on a surface thereof. For example, a Sn layer is formed as the metal layer 80. Such a metal layer 80 is formed, for example, by electroless Sn plating. The metal layer 80 is formed, for example, by a heat treatment described later at a thickness at which Sn is contained in such an amount that the total amount of Ni contained in the metal layer 70 thereunder is stable Ni—Sn.

After the formation of the metal layer 80, a heat treatment is performed at a temperature equal to or higher than the melting point thereof, for example, at a temperature equal to or higher than 231° C. if the metal layer 80 is a Sn layer. By such a heat treatment, a reaction between Sn contained in the metal layer 80 and Ni contained in the metal layer 70 thereunder proceeds, and as illustrated in FIG. 7B, the stable compound layer 30 of Ni—Sn is formed. Furthermore, in this heat treatment, along with the formation of the stable compound layer 30 of Ni—Sn by the reaction between Ni and Sn, the remaining components other than Ni contained in the metal layer 70, that is, B, B—P, B—W, B—Co, B—P—W, or B—P—Co is segregated immediately below the compound layer 30. As a result, as illustrated in FIG. 7B, the isolation layer 40 of B, B—P, B—W, B—Co, B—P—W, or B—P—Co is formed between the compound layer 30 and the conductor portion 20.

B, P, W, or Co of the isolation layer 40 segregated along with the formation of the stable compound layer 30 of Ni—Sn by the heat treatment does not form or hardly forms a compound with Cu contained in the conductor portion 20 or Sn contained in the metal layer 80 or the compound layer 30. During the heat treatment, the isolation layer 40 to be formed exhibits a barrier function, and this barrier function suppresses a reaction between Cu contained in the conductor portion 20 and Sn contained in the metal layer 80 or the compound layer 30. During the heat treatment, Ni contained in the metal layer 70 reacts with Sn contained in the metal layer 80 to change into stable Ni—Sn. Such stabilization of Ni and such a barrier function of the isolation layer 40 suppress a reaction between Cu contained in the conductor portion 20 and Ni contained in the metal layer 70 or the compound layer 30. As a result, a reduction in the size of the conductor portion 20 from the size before the heat treatment (FIG. 7A) and an increase in the resistance of the conductor portion 20 due to the reduction in the size are suppressed.

In such a heat treatment in which the compound layer 30 and the isolation layer 40 are formed, the whole amount of Ni contained in the metal layer 70 desirably reacts with Sn contained in the metal layer 80 to change into the stable compound layer 30. This is for suppressing formation of Cu—Ni by Ni remaining without reacting with Sn by alloying with Cu contained in the conductor portion 20 due to heat applied thereafter. By taking such points into consideration, the thickness (Ni amount) of the metal layer 70 and the thickness (Sn amount) of the metal layer 80 formed thereon are adjusted.

After the heat treatment for forming the compound layer 30 and the isolation layer 40, the metal layer 80 containing Sn not consumed for forming the compound layer 30 may remain or does not have to remain on a surface of the formed compound layer 30. FIG. 7B exemplifies a case where the metal layer 80 remains on a surface of the compound layer 30.

When the metal layer 80 remains on a surface of the compound layer 30 after the heat treatment, as illustrated in FIG. 7C, the remaining metal layer 80 is removed. For example, the metal layer 80 containing Sn is selectively removed with respect to the compound layer 30 of Ni—Sn by wet etching. By removing the remaining metal layer 80, diffusion of Sn not consumed for forming the stable compound layer 30 of Ni—Sn into the conductor portion 20, the insulating layer 50 described later, or the like due to heat applied thereafter is suppressed.

When the metal layer 80 does not remain on a surface of the compound layer 30 after the heat treatment, that is, when the structure as illustrated in FIG. 7C is obtained after the heat treatment, the wet etching for removing Sn as described above does not necessarily have to be performed.

By the steps as described above, the electronic component 1A as illustrated in FIG. 7C, having a structure in which the conductor portion 20 on the substrate 10 is covered with the stable compound layer 30 through the isolation layer 40, is obtained.

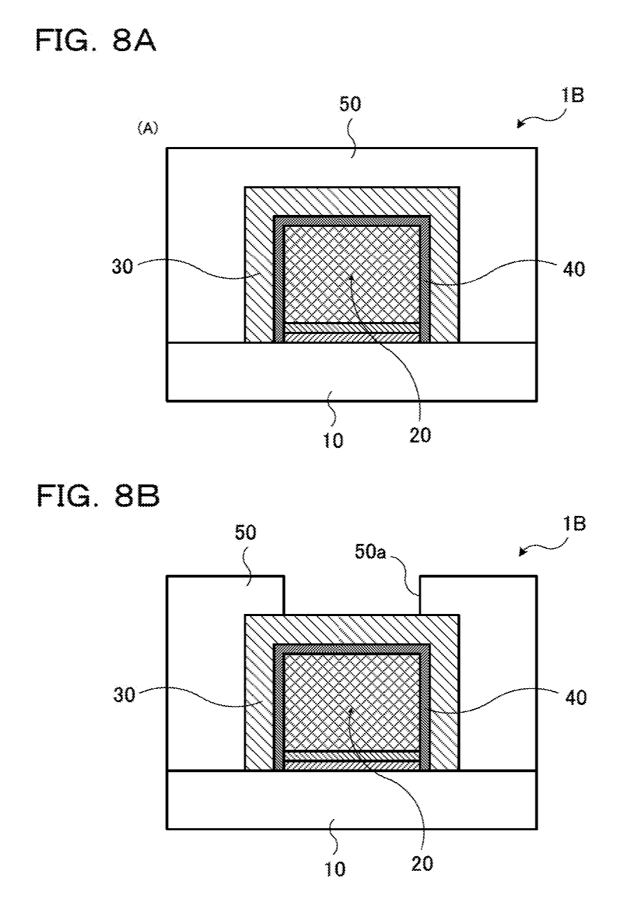

If the insulating layer 50 is formed so as to cover the conductor portion 20, the isolation layer 40, and the compound layer 30 on the substrate 10, the electronic component 1B as illustrated in FIG. 8A is obtained.

For example, when the conductor portion 20 is used as an external connection terminal (a part thereof) of the electronic component 1B, for example, as illustrated in FIG. 8B, an opening 50a leading to the compound layer 30 as an outermost layer may be disposed in the insulating layer 50. In this case, an opening communicating with the opening 50a of the insulating layer 50 may be disposed in the compound layer 30 to expose an upper surface of the isolation layer 40, or an opening communicating with the opening 50a of the insulating layer 50 may be disposed in the compound layer 30 and the isolation layer 40 to expose an upper surface of the conductor portion 20.

In the electronic components 1A and 1B, the stable compound layer 30 is disposed around the conductor portion 20 on the substrate 10, and between the conductor portion 20 and the compound layer 30, the isolation layer 40 isolating elements contained therein from each other is disposed. As a result, a reaction between Cu contained in the conductor portion 20 and an element outside the conductor portion 20, such as Ni or Sn of the compound layer 30, is suppressed, and a reduction in the size of the conductor portion 20 due to such a reaction and an increase in the resistance of the conductor portion 20 are suppressed.

Specific Examples of the electronic components 1A and 1B will be described below.

### EXAMPLE 1

A resin substrate was used as the substrate 10, and using a sputtering device, a Ti film 21a having a thickness of 50 nm and a Cu film 21b having a thickness of 100 nm were formed as the seed layer 21 on the entire surface of the substrate 10 (FIG. 5A). After the formation of the seed layer 21, the resist 60 having a thickness of 2 μm was applied to the entire surface of the substrate 10, and the opening 60a was subjected to patterning at a wiring width of 1 μm using an exposure device and a developing device (FIG. 5B). After patterning, the resulting product was immersed in an electrolytic Cu plating solution, and electricity was supplied to the seed layer 21 to perform electrolytic Cu plating, thereby forming the conductor layer 22 (FIG. 5C). The conductor layer 22 had a height of 1 μm.

After electrolytic Cu plating, the resulting product was immersed in a resist peeling solution to remove the resist 60 (FIG. 6A), and further immersed in a Cu etching solution and a Ti etching solution to remove the seed layer 21, thereby forming Cu wiring as the conductor portion 20 (FIG. 6B). After the formation of the conductor portion 20, the resulting product was immersed in 10 wt % sulfuric acid, washed with pure water, and immersed in an electroless Ni—B plating solution to form Ni—B as the metal layer 70 on a side surface and an upper surface of the conductor portion 20 (FIG. 6C). Ni—B had a thickness of 100 nm and a B concentration of 5.0 wt % therein.

After the formation of Ni—B as the metal layer 70, the resulting product was immersed in 10 wt % sulfuric acid, washed with pure water, and immersed in an electroless Sn plating solution to form Sn as the metal layer 80 on a side surface and an upper surface of the metal layer 70 (FIG. 7A). Sn had a thickness of 150 nm. After the formation of Sn as the metal layer 80, Sn of the metal layer 80 was melted by a heat treatment at 250° C. using a reflow device. When Sn of the metal layer 80 melted and reacted with Ni—B of the metal layer 70, the whole amount of Ni was consumed in the reaction to form the compound layer 30 of Ni—Sn as an intermetallic compound, and a segregation layer of B to be the isolation layer 40 was formed on a side surface and an upper surface of the Cu wiring as the conductor portion 20 (FIG. 7B). B had a thickness of 10 nm. Sn of the metal layer 80 remained on a side surfaces and an upper surface of the compound layer 30 of Ni—Sn (FIG. 7B). After the formation of the isolation layer 40 and the compound layer 30, the resulting product was immersed in a Sn etching solution to remove remaining Sn of the metal layer 80, thereby obtaining the electronic component 1A (FIG. 7C).

Furthermore, after the removal of the remaining metal layer 80, a polybenzoxazole-based resin layer was formed as the insulating layer 50 on the substrate 10 to obtain the electronic component 1B (FIG. 8A or 8B).

### EXAMPLE 2

A Si substrate was used as the substrate 10, and using a sputtering device, a Ti film 21a having a thickness of 30 nm and a Cu film 21b having a thickness of 80 nm were formed as the seed layer 21 on the entire surface of the substrate 10 (FIG. 5A). After the formation of the seed layer 21, the resist 60 having a thickness of 4 μm was applied to the entire surface of the substrate 10, and the opening 60a was subjected to patterning at a wiring width of 2 μm using an exposure device and a developing device (FIG. 5B). After patterning, the resulting product was immersed in an electrolytic Cu plating solution, and electricity was supplied to the seed layer 21 to perform electrolytic Cu plating, thereby forming the conductor layer 22 (FIG. 5C). The conductor layer 22 had a height of 2 μm.

After electrolytic Cu plating, the resulting product was immersed in a resist peeling solution to remove the resist 60 (FIG. 6A), and further immersed in a Cu etching solution and a Ti etching solution to remove the seed layer 21, thereby forming Cu wiring as the conductor portion 20 (FIG. 6B). After the formation of the conductor portion 20, the resulting product was immersed in 10 wt % sulfuric acid, washed with pure water, and immersed in an electroless Ni—B—P plating solution to form Ni—B—P as the metal layer 70 on a side surface and an upper surface of the conductor portion 20 (FIG. 6C). Ni—B—P had a thickness of 100 nm, a B concentration of 0.3 wt % therein, and a P concentration of 3.0 wt % therein.

After the formation of Ni—B—P as the metal layer 70, the resulting product was immersed in 10 wt % sulfuric acid, washed with pure water, and immersed in an electroless Sn plating solution to form Sn as the metal layer 80 on a side surface and an upper surface of the metal layer 70 (FIG. 7A). Sn had a thickness of 150 nm. After the formation of Sn as the metal layer 80, Sn of the metal layer 80 was melted by a heat treatment at 250° C. using a reflow device. When Sn of the metal layer 80 melted and reacted with Ni—B—P of the metal layer 70, the whole amount of Ni was consumed in the reaction to form the compound layer 30 of Ni—Sn as an intermetallic compound, and a segregation layer of B—P to be the isolation layer 40 was formed on a side surface and an upper surface of the Cu wiring as the conductor portion 20 (FIG. 7B). B—P had a thickness of 8 nm. Sn of the metal layer 80 remained on a side surfaces and an upper surface of the compound layer 30 of Ni—Sn (FIG. 7B). After the formation of the isolation layer 40 and the compound layer 30, the resulting product was immersed in a Sn etching solution to remove remaining Sn of the metal layer 80, thereby obtaining the electronic component 1A (FIG. 7C).

Furthermore, after the removal of the remaining metal layer 80, a polyimide-based resin layer was formed as the insulating layer 50 on the substrate 10 to obtain the electronic component 1B (FIG. 8A or 8B).

Next, a second embodiment will be described.

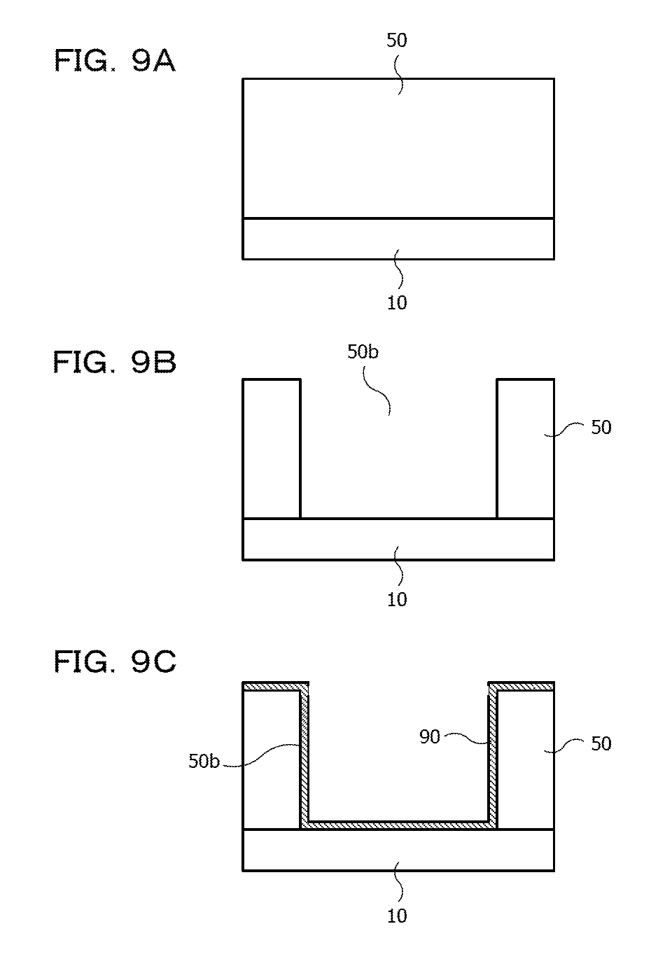

FIGS. 9A to 12B are views illustrating an example of a method for forming an electronic component according to the second embodiment. FIGS. 9A to 9C, FIGS. 10A and 10B, FIGS. 11A and 11B, and FIGS. 12A and 12B each schematically illustrate a cross-section of a main part in each step of an example of the method for forming an electronic component according to the second embodiment.

In this example, first, as illustrated in FIG. 9A, an insulating layer 50 is formed on a substrate 10. As the substrate 10, various substrates such as a semiconductor substrate of Si or the like, a resin substrate of polyimide or the like, an interlayer insulating film made of an organic material or an inorganic material, a glass substrate, and a ceramic substrate are used. As the insulating layer 50, various insulating layers such as a resin layer of polyimide or the like and an interlayer insulating film made of an organic material or an inorganic material are used.

An opening 50b is formed in the insulating layer 50 on the substrate 10 as illustrated in FIG. 9B. The opening 50b is formed in a region where a conductor portion 20 to be formed as wiring or a via as described later, metal layers 70 and 80 formed outside the conductor portion 20, and a barrier metal layer 90 are to be disposed. The opening 50b is formed using an etching technique, a laser processing technique, or the like depending on a material of the insulating layer 50.

After the formation of the opening 50b in the insulating layer 50, as illustrated in FIG. 9C, the barrier metal layer 90 is formed. As the barrier metal layer 90, Ti, tantalum (Ta), a nitride thereof, or the like is formed. The barrier metal layer 90 is formed on an inner surface (sidewall and bottom surface) of the opening 50b of the insulating layer 50 and an upper surface of the insulating layer 50 by a sputtering method or a chemical vapor deposition (CVD) method.

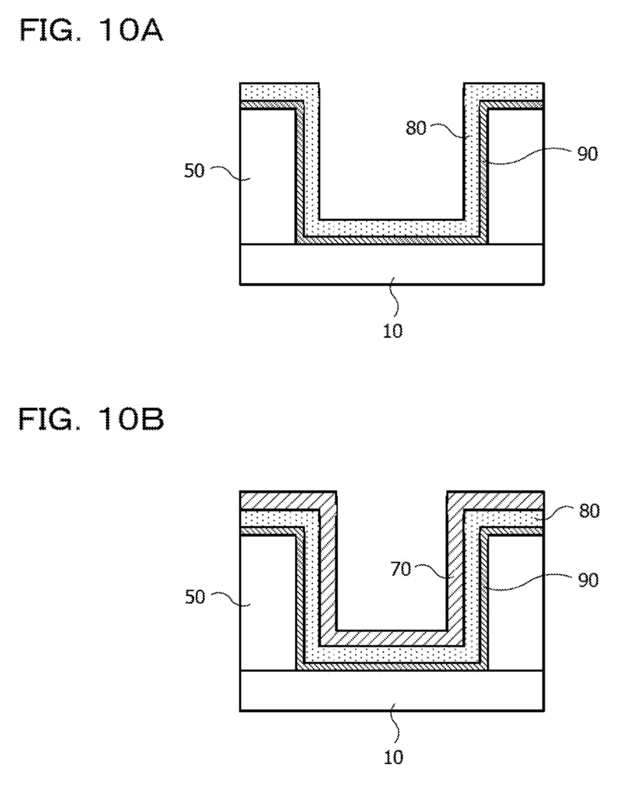

After the formation of the barrier metal layer 90, as illustrated in FIG. 10A, the metal layer 80 is formed on a surface of the barrier metal layer 90. As the metal layer 80, for example, a Sn layer is formed. The Sn layer is formed by sputtering Sn. The metal layer 80 is formed, for example, by a heat treatment described later at a thickness at which Sn is contained in such an amount that the total amount of Ni contained in the metal layer 70 to be formed thereon is stable Ni—Sn.

After the formation of the metal layer 80, as illustrated in FIG. 10B, the metal layer 70 is further formed on a surface of the metal layer 80. As the metal layer 70, for example, a metal layer containing Ni and B is formed. The metal layer 70 is formed, for example, by sputtering Ni—B, Ni—B—P, Ni—B-W, Ni—B—Co, Ni—B—P—W, or B—P-Co. The metal layer 70 may be formed by sputtering B, P, W, and Co after sputtering Ni.

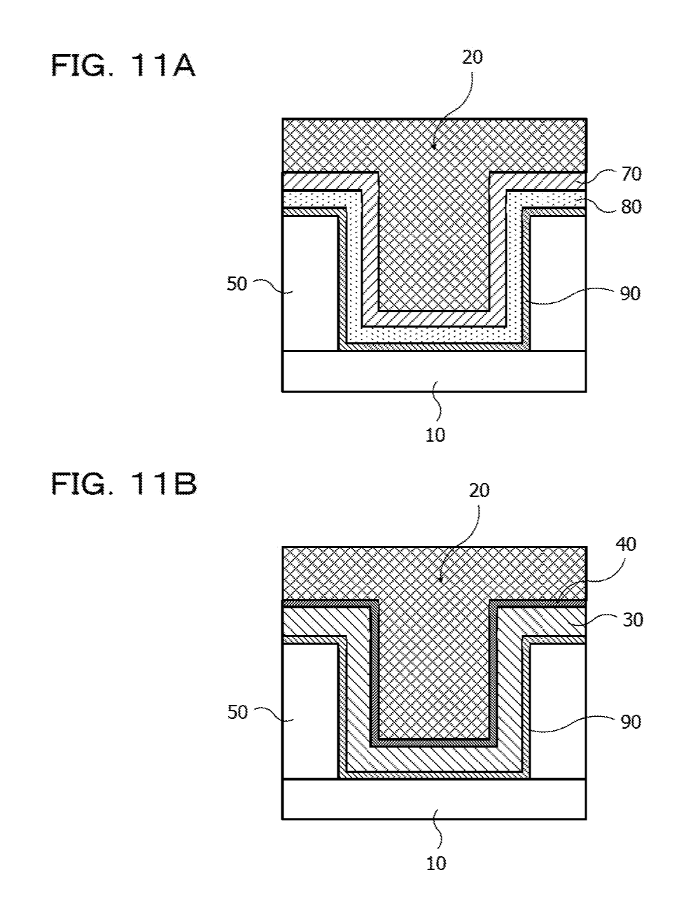

After the formation of the metal layer 70, as illustrated in FIG. 11A, the conductor portion 20 is formed on a surface of the metal layer 70. The conductor portion 20 is, for example, wiring or a via. As the conductor portion 20, for example, a Cu layer is formed. The conductor portion 20 is formed by a plating method, a CVD method, or the like. When the conductor portion 20 is formed by the plating method, at least one of the metal layer 80 and the metal layer 70 can be used as a feeding layer at the time of electrolytic plating, and a seed layer (not illustrated) can be formed on the metal layer 70 to be used as the feeding layer at the time of electrolytic plating.

After the formation of the conductor portion 20, a heat treatment is performed at a temperature equal to or higher than the melting point of the metal layer 80, for example, at a temperature equal to or higher than 231° C. if the metal layer 80 is a Sn layer. By such a heat treatment, as illustrated in FIG. 11B, a reaction between Sn contained in the metal layer 80 and Ni contained in the metal layer 70 thereon proceeds, and the stable compound layer 30 of Ni—Sn is formed. Furthermore, in this heat treatment, along with the formation of the stable compound layer 30 of Ni—Sn by the reaction between Ni and Sn, the remaining components other than Ni contained in the metal layer 70, that is, B, B—P, B—W, B—Co, B—P—W, or B—P—Co is segregated immediately above the compound layer 30. As a result, as illustrated in FIG. 11B, the isolation layer 40 of B, B—P, B—W, B—Co, B—P—W, or B—P—Co is formed between the compound layer 30 and the conductor portion 20.

B, P, W, or Co of the isolation layer 40 does not form or hardly forms a compound with Cu contained in the conductor portion 20 or Sn contained in the metal layer 80 or the compound layer 30. Therefore, during the heat treatment, the isolation layer 40 to be formed exhibits a barrier function, and this barrier function suppresses a reaction between Cu contained in the conductor portion 20 and Sn contained in the metal layer 80 or the compound layer 30. During the heat treatment, Ni contained in the metal layer 70 reacts with Sn contained in the metal layer 80 to change into stable Ni—Sn. Such stabilization of Ni and such a barrier function of the isolation layer 40 suppress a reaction between Cu contained in the conductor portion 20 and Ni contained in the metal layer 70 or the compound layer 30. As a result, a reduction in the size of the conductor portion 20 from the size before the heat treatment (FIG. 11A) and an increase in the resistance of the conductor portion 20 due to the reduction in the size are suppressed.

In such a heat treatment in which the compound layer 30 and the isolation layer 40 are formed, the whole amount of Ni contained in the metal layer 70 desirably reacts with Sn contained in the metal layer 80 to change into the stable compound layer 30. The whole amount of Sn contained in the metal layer 80 desirably reacts with Ni contained in the metal layer 70 to change into the stable compound layer 30. This is for suppressing diffusion of Ni remaining without reacting with Sn and Sn remaining without reacting with Ni into the conductor portion 20, the insulating layer 50, or the like due to heat applied thereafter. By taking such points into consideration, the thickness (Ni amount) of the metal layer 70 and the thickness (Sn amount) of the metal layer 80 formed thereon are adjusted.

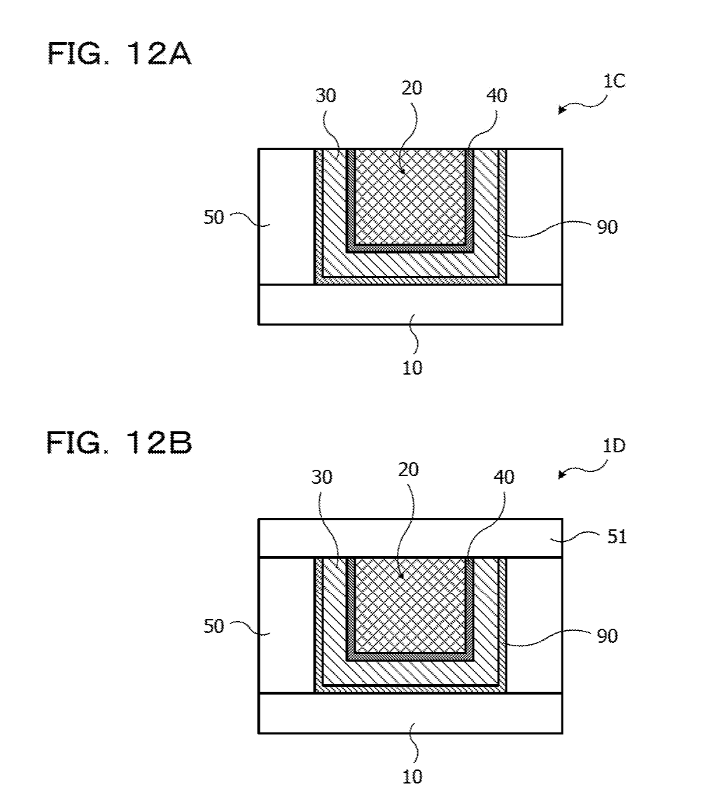

After the heat treatment, as illustrated in FIG. 12A, the unnecessary conductor portion 20, the unnecessary isolation layer 40, the unnecessary compound layer 30, and the unnecessary barrier metal layer 90 formed on the upper surface of the insulating layer 50 are ground and removed by chemical mechanical polishing (CMP) or the like. As a result, an electronic component 1C as illustrated in FIG. 12A, having a structure in which the conductor portion 20 in the insulating layer 50 disposed on the substrate 10 is covered with the stable compound layer 30 and the barrier metal layer 90 through the isolation layer 40, is obtained.

If an insulating layer 51 is further formed so as to cover the conductor portion 20, the isolation layer 40, the compound layer 30, and the barrier metal layer 90 in the insulating layer 50, an electronic component 1D as illustrated in FIG. 12B is obtained. As the insulating layer 51, various insulating layers such as a resin layer of polyimide or the like and an interlayer insulating film made of an organic material or an inorganic material are used.

As described above, in the electronic components 1C and 1D, a surface of the conductor portion 20 embedded in the insulating layer 50 is covered with the isolation layer 40, and the isolation layer 40 is covered with the compound layer 30.

When the conductor portion 20 contains Cu, the isolation layer 40 contains B, and the compound layer 30 contains Ni and Sn, Ni of the compound layer 30 forms a stable intermetallic compound with Sn. Meanwhile, B of the isolation layer 40 does not form or hardly forms a compound with Cu of the conductor portion 20 or Sn and Ni of the compound layer 30.

In the electronic components 1C and 1D, a reaction between B contained in the isolation layer 40 and Cu contained in the conductor portion 20 inside the isolation layer 40 is suppressed, and a reaction between B contained in the isolation layer 40 and Sn contained in the compound layer 30 outside the isolation layer 40 is suppressed. Ni contained in the compound layer 30 outside the isolation layer 40 forms a stable intermetallic compound with Sn, and B or the like is segregated along with the formation to form the isolation layer 40. The isolation layer 40 containing B isolates Cu contained in the conductor portion 20 from Ni and Sn contained in the compound layer 30, and exhibits a barrier function to suppress diffusion thereof and a reaction therebetween.

In the electronic components 1C and 1D, the barrier function of the isolation layer 40 suppresses a reaction between Cu contained in the conductor portion 20 and Ni and Sn contained in the compound layer 30 outside the conductor portion 20. By suppressing the reaction between Cu in the conductor portion 20 and an element outside the conductor portion 20 in this manner, reduction in the size of the conductor portion 20 from its original size and an increase in the resistance of the conductor portion 20 due to the reduction in the size are suppressed.

In the electronic components 1C and 1D each including the conductor portion 20, the isolation layer 40, and the compound layer 30 as described above, a reaction of the conductor portion 20 with an element present at an outside thereof, reduction in size due to the reaction, and an increase in resistance due to the reduction in the size are suppressed. As a result, the electronic components 1C and 1D having excellent performance and reliability are achieved.

The combination of elements contained in the conductor portion 20, the isolation layer 40, and the compound layer 30 of the electronic components 1C and 1D is not limited to the above example (Cu, B, Ni, and Sn). The combination of elements is not limited as long as the conductor portion 20 is used as wiring or a via, the compound layer 30 is formed as a stable compound, and the isolation layer 40 is present between the conductor portion 20 and the compound layer 30 and suppresses diffusion and reaction of elements contained therein.

Next, a third embodiment will be described.

Here, application examples of the conductor portion 20, the isolation layer 40, and the compound layer 30 as described in the first and second embodiments will be described as the third embodiment.

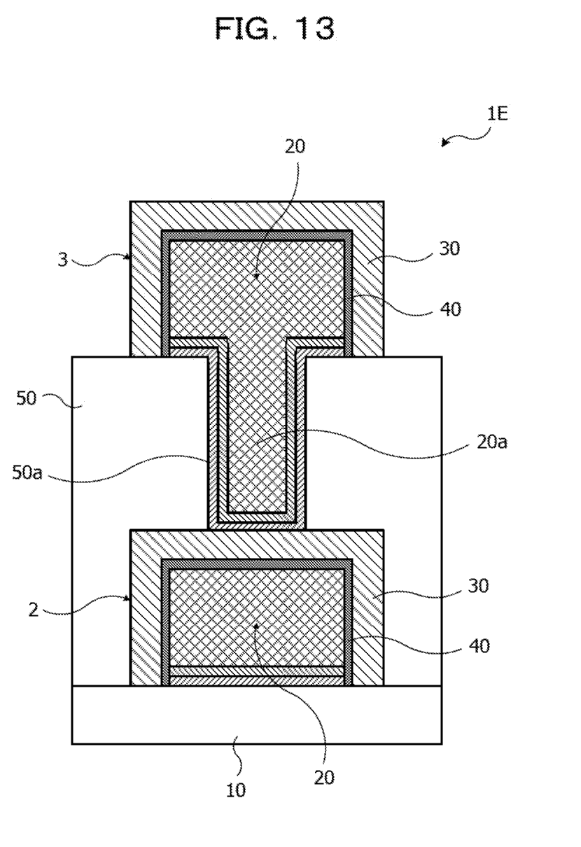

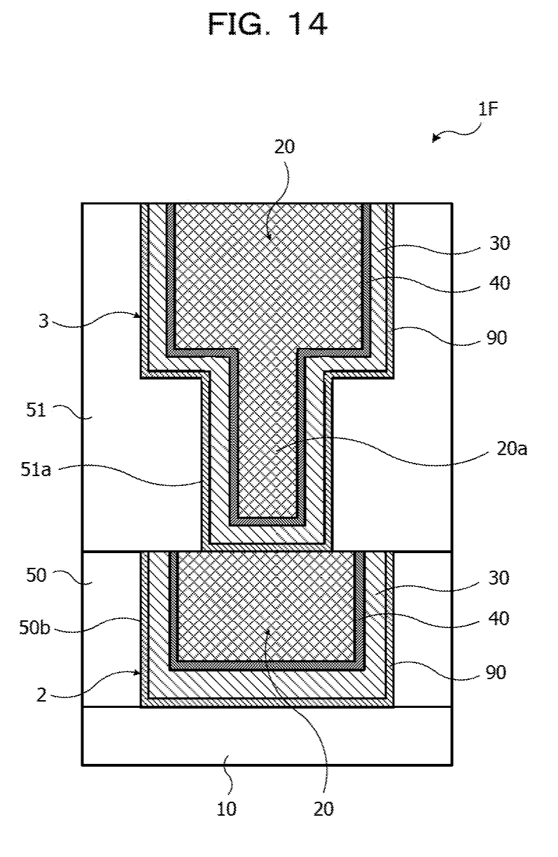

FIGS. 13 and 14 are views illustrating an example of an electronic component according to the third embodiment. FIG. 13 schematically illustrates a cross-section of a main part of a first example of the electronic component according to the third embodiment. FIG. 14 schematically illustrates a cross-section of a main part of a second example of the electronic component according to the third embodiment.

An electronic component 1E illustrated in FIG. 13 includes a laminate 2 including a conductor portion 20 (wiring) disposed on a substrate 10, an isolation layer 40 covering a surface of the conductor portion 20, and a compound layer 30 covering a surface of the isolation layer 40. The laminate 2 is covered with an insulating layer 50. On the insulating layer 50, a laminate 3 including the conductor portion 20 (wiring) having a connection portion (via) 20a connected to the laminate 2, the isolation layer 40 covering a surface of the conductor portion 20, and the compound layer 30 covering a surface of the isolation layer 40 is disposed.

The laminate 2 and the insulating layer 50 on the substrate 10 are formed by the above method as illustrated in FIGS. 5A to 8C. The laminate 3 on the insulating layer 50 is formed on the insulating layer 50 having an opening 50a (via hole) communicating with the laminate 2 according to the example of the above method as illustrated in FIGS. 5A to 8C.

In the electronic component 1E, each of the conductor portions 20 formed of upper and lower layer wiring connected by the connection portion 20a of the via is covered with the compound layer 30 through the isolation layer 40. For example, the stable compound layer 30 of Ni—Sn is disposed around the conductor portion 20 containing Cu, and between the conductor portion 20 and the compound layer 30, the isolation layer 40 formed by segregation of B or the like along with the formation of the compound layer 30 is disposed. A barrier function of the isolation layer 40 suppresses a reaction between Cu in the conductor portion 20 and an element outside the conductor portion 20, and suppresses reduction in the size of the conductor portion 20 and an increase in the resistance of the conductor portion 20 due to the reduction in the size. As a result, the electronic component 1E having excellent performance and reliability is achieved.

An electronic component 1F illustrated in FIG. 14 includes the laminate 2 including the conductor portion 20 (wiring) disposed in the insulating layer 50 on the substrate 10, the isolation layer 40 covering a surface of the conductor portion 20, and the compound layer 30 covering a surface of the isolation layer 40. An insulating layer 51 is disposed on the insulating layer 50 and the laminate 2. In the insulating layer 51, a laminate 3 including the conductor portion 20 (wiring) having a connection portion (via) 20a connected to the laminate 2, the isolation layer 40 covering a surface of conductor portion 20, and the compound layer 30 covering a surface of the isolation layer 40 is disposed.

The insulating layer 50 and the laminate 2 on the substrate 10 are formed by the above method as illustrated in FIGS. 9A to 12B. The insulating layer 51 and the laminate 3 thereon are formed by disposing an opening 51a communicating with the laminate 2 (via hole and wiring groove communicating therewith) in the insulating layer 51 according to the example of the above method as illustrated in FIGS. 9A to 12B.

In the electronic component 1F, the conductor portion 20 as lower layer wiring and the conductor portion 20 as upper layer wiring including the connection portion 20a of the via connected thereto are both covered with the compound layer 30 through the isolation layer 40. For example, the stable compound layer 30 of Ni—Sn is disposed around the conductor portion 20 containing Cu and the connection portion 20a, and between the conductor portion 20 and the compound layer 30 and between the connection portion 20a and the compound layer 30, the isolation layer 40 formed by segregation of B or the like along with the formation of the compound layer 30 is disposed. A barrier function of the isolation layer 40 suppresses a reaction between Cu in the conductor portion 20 and the connection portion 20a and an element outside the conductor portion 20 and the connection portion 20a, and suppresses a reduction in the sizes of the conductor portion 20 and the connection portion 20a and an increase in the resistances of the conductor portion 20 and the connection portion 20a due to the reduction in the sizes. As a result, the electronic component 1F having excellent performance and reliability is achieved.

Next, a fourth embodiment will be described.

Here, an example of an electronic component to which the conductor portion 20, the isolation layer 40, and the compound layer 30 as described in the first to third embodiments are applicable will be described as the fourth embodiment.

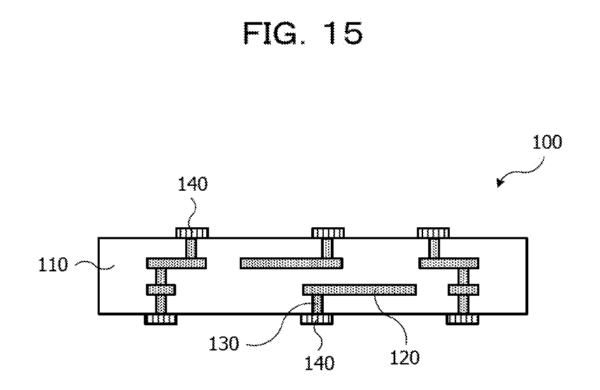

FIG. 15 is a view illustrating an example of a circuit board according to the fourth embodiment. FIG. 15 schematically illustrates a cross-section of a main part of an example of the circuit board according to the fourth embodiment.

FIG. 15 exemplifies a circuit board 100. As the circuit board 100, various circuit boards such as a multilayer printed board, a buildup board in which wiring patterns and insulating layers are laminated on front and back surfaces of a core substrate, and an interposer using a Si substrate, a resin substrate, or a glass substrate as a base material are used. The circuit board 100 includes an insulating layer 110 made of an organic material or an inorganic material, wiring 120 and a via 130 disposed in the insulating layer 110, and an electrode 140 electrically connected thereto and disposed on a surface of the insulating layer 110.

The configuration described in any one of the first to third embodiments is applied to at least one of the wiring 120, the via 130, and the electrode 140 in such a circuit board 100. That is, the configuration having, between the conductor portion 20 and the stable compound layer 30 therearound, the isolation layer 40 isolating elements thereof from each other is applied. In the wiring 120, the via 130, or the electrode 140 to which such a configuration is applied, a reaction thereof with an element present at an outside thereof, a reduction in size due to the reaction, and an increase in resistance due to the reduction in size are suppressed. As a result, the circuit board 100 having excellent performance and reliability is achieved.

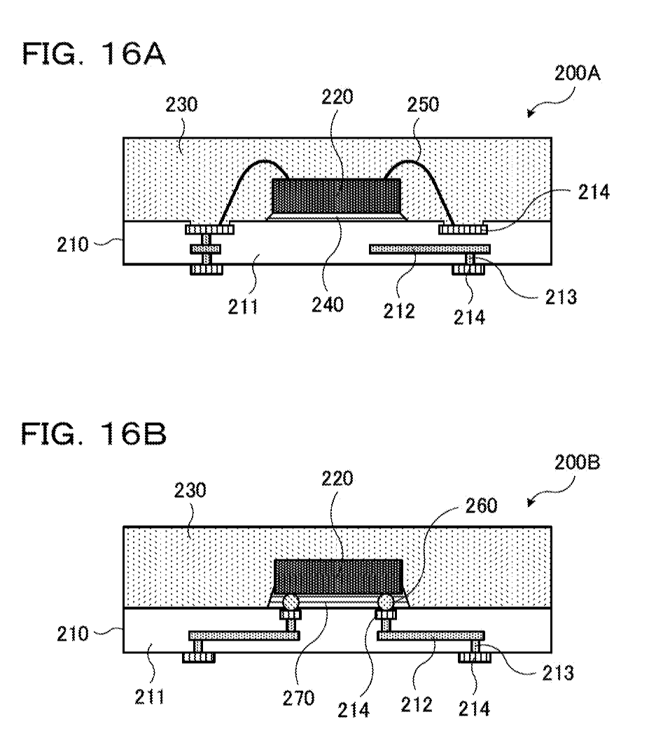

FIGS. 16A and 16B are views illustrating an example of a semiconductor package according to the fourth embodiment. FIGS. 16A and 16B each schematically illustrates a cross-section of a main part of an example of the semiconductor package according to the fourth embodiment.

A semiconductor package 200A (semiconductor device) illustrated in FIG. 16A and a semiconductor package 200B (semiconductor device) illustrated in FIG. 16B each include a package substrate 210 (circuit board), a semiconductor chip 220 (semiconductor element) mounted on the package substrate 210, and a sealing layer 230 sealing the semiconductor chip 220.

In the semiconductor package 200A of FIG. 16A, the semiconductor chip 220 is fixed to the package substrate 210 by a die attach material 240, and is wire-bonded by a wire 250. The semiconductor chip 220 and the wire 250 are sealed by the sealing layer 230. In the semiconductor package 200B of FIG. 16B, the semiconductor chip 220 is flip chip bonded to the package substrate 210 by a bump 260 such as solder. An underfill resin 270 is filled between the package substrate 210 and the semiconductor chip 220.

The package substrate 210 includes an insulating layer 211 made of an organic material or an inorganic material, wiring 212 and a via 213 disposed in the insulating layer 211, and an electrode 214 electrically connected thereto and disposed on a surface of the insulating layer 211.

The configuration described in any one of the first to third embodiments is applied to at least one of the wiring 212, the via 213, and the electrode 214 in the package substrate 210 in such semiconductor packages 200A and 200B. That is, the configuration having, between the conductor portion 20 and the stable compound layer 30 therearound, the isolation layer 40 isolating elements thereof from each other is applied. In the wiring 212, the via 213, or the electrode 214 to which such a configuration is applied, a reaction thereof with an element present at an outside thereof, a reduction in size due to the reaction, and an increase in resistance due to the reduction in size are suppressed. As a result, the semiconductor packages 200A and 200B having excellent performance and reliability are achieved.

On the package substrate 210 of each of the semiconductor packages 200A and 200B, a plurality of semiconductor chips 220 of the same type or different types may be mounted, or another electronic component such as a chip capacitor may be mounted in addition to the semiconductor element 220.

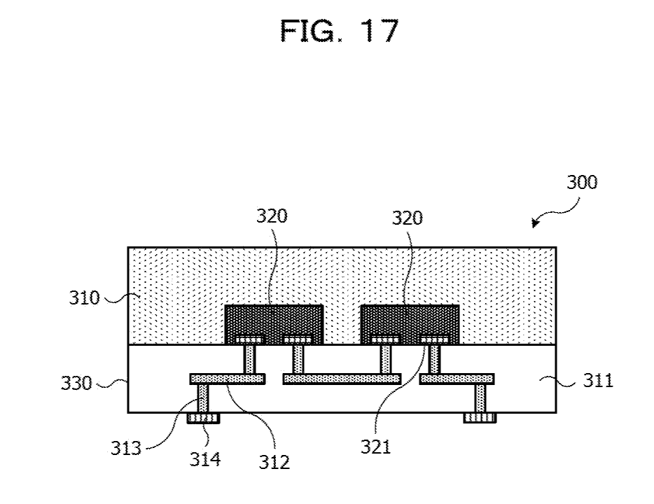

FIG. 17 is a view illustrating another example of the semiconductor package according to the fourth embodiment. FIG. 17 schematically illustrates a cross-section of a main part of another example of the semiconductor package according to the fourth embodiment.

A semiconductor package 300 illustrated in FIG. 17 includes a resin layer 310, a plurality of semiconductor chips 320 (two semiconductor chips 320 are exemplified here) of the same type or different types embedded in the resin layer 310, and a wiring layer 330 (rewiring layer) disposed on the resin layer 310. The semiconductor package 300 is also referred to as a wafer level package (WLP), a pseudo system on a chip (SoC), or the like.

The semiconductor chips 320 are embedded in the resin layer 310 such that disposition surfaces of electrodes 321 thereof are exposed. The wiring layer 330 includes an insulating layer 311 made of an organic material or an inorganic material, wiring 312 (rewiring) and a via 313 disposed in the insulating layer 311, and an electrode 314 electrically connected thereto and disposed on a surface of the insulating layer 311.

The configuration described in any one of the first to third embodiments is applied to at least one of the wiring 312, the via 313, and the electrode 314 in the wiring layer 330 in such a semiconductor package 300. That is, the configuration having, between the conductor portion 20 and the stable compound layer 30 therearound, the isolation layer 40 isolating elements thereof from each other is applied. In the wiring 312, the via 313, or the electrode 314 to which such a configuration is applied, a reaction thereof with an element present at an outside thereof, a reduction in size due to the reaction, and an increase in resistance due to the reduction in size are suppressed. As a result, the semiconductor package 300 having excellent performance and reliability is achieved.

In the resin layer 310 of the semiconductor package 300, one semiconductor chip 320 or three or more semiconductor chips 320 of the same type or different types may be embedded, or another electronic component such as a chip capacitor may be mounted in addition to the semiconductor chip 320.

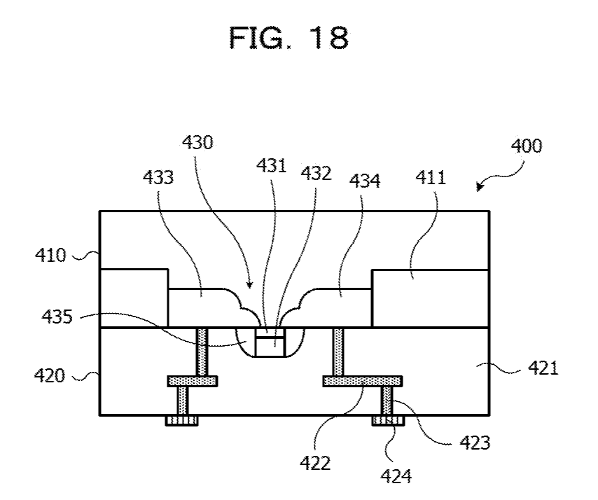

FIG. 18 is a view illustrating an example of the semiconductor chip according to the fourth embodiment. FIG. 18 schematically illustrates a cross-section of a main part of an example of the semiconductor chip according to the fourth embodiment.

A semiconductor chip 400 illustrated in FIG. 18 includes a semiconductor substrate 410 having a circuit element such as a transistor and a wiring layer 420 disposed on the semiconductor substrate 410.

As the semiconductor substrate 410, in addition to a substrate of Si, germanium (Ge), silicon germanium (SiGe), or the like, a substrate of gallium nitride (GaN), gallium arsenide (GaAs), indium phosphorus (InP), or the like is used. On such a semiconductor substrate 410, a circuit element such as a transistor, a capacitor, or a resistor is disposed. FIG. 18 illustrates a metal oxide semiconductor (MOS) transistor 430 as an example.

The MOS transistor 430 is disposed in an element region defined by an element isolation region 411 disposed on the semiconductor substrate 410. The MOS transistor 430 has a gate electrode 432 formed on the semiconductor substrate 410 through a gate insulating film 431, and a source region 433 and a drain region 434 formed in the semiconductor substrate 410 on both sides of the gate electrode 432. An insulating film spacer 435 (sidewall) is disposed on a sidewall of the gate electrode 432.

A wiring layer 420 is disposed on the semiconductor substrate 410 having the MOS transistor 430 or the like. The wiring layer 420 includes an insulating layer 421 made of an organic material or an inorganic material, wiring 422 and a via 423 disposed in the insulating layer 421, and an electrode 424 electrically connected thereto and disposed on a surface of the insulating layer 421.

The configuration described in any one of the first to third embodiments is applied to at least one of the wiring 422, the via 423, and the electrode 424 in the wiring layer 420 in such a semiconductor chip 400. That is, the configuration having, between the conductor portion 20 and the stable compound layer 30 therearound, the isolation layer 40 isolating elements thereof from each other is applied. In the wiring 422, the via 423, or the electrode 424 to which such a configuration is applied, a reaction thereof with an element present at an outside thereof, a reduction in size due to the reaction, and an increase in resistance due to the reduction in size are suppressed. As a result, the semiconductor chip 400 having excellent performance and reliability is achieved.

Similarly to the semiconductor chip 400, the configuration described in any one of the first to third embodiments is applicable to the semiconductor chips 220, 320, and the like of the semiconductor packages 200A and 200B (FIGS. 16A and 16B) and the semiconductor packages 300 (FIG. 17).

As described above, the configuration including the conductor portion 20, the isolation layer 40, and the compound layer 30 as described in the first to third embodiments is applicable to various electronic components such as the circuit board 100, the semiconductor packages 200A, 200B, and 300, and the semiconductor chip 400.

Next, a fifth embodiment will be described.

Various electronic devices can be obtained using electronic components including the conductor portion 20, the isolation layer 40, and the compound layer 30 as described in the first to third embodiments. Here, an example of the electronic device will be described as the fifth embodiment.

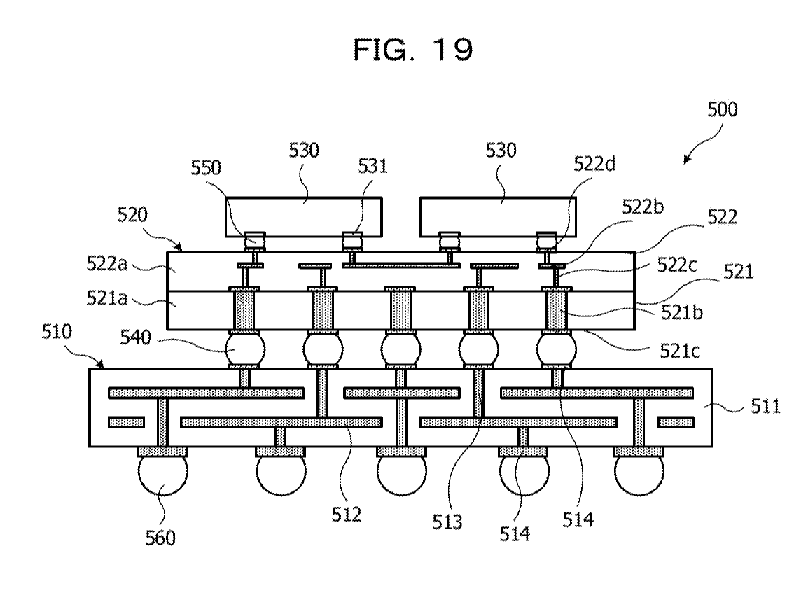

FIGS. 19A and 19B are views illustrating an example of the electronic device according to the fifth embodiment. FIGS. 19A and 19B each schematically illustrate a cross-section of a main part of an example of the electronic device according to the fifth embodiment.

An electronic device 500 illustrated in FIG. 19 includes a circuit board 510, an interposer 520 (circuit board) mounted on the circuit board 510, and a plurality of semiconductor chips 530 (two semiconductor chips 530 are exemplified here) of the same type or different types mounted on the interposer 520. The circuit board 510 and the interposer 520 are electrically connected to each other by a bump 540 such as solder, and the interposer 520 and the semiconductor chip 530 are electrically connected to each other by a bump 550 such as solder. A bump 560 such as solder is disposed on the circuit board 510 for external connection of the electronic device 500.

In the circuit board 510, an insulating layer 511 made of an organic material or an inorganic material, wiring 512 and a via 513 disposed in the insulating layer 511, and an electrode 514 electrically connected thereto and disposed on a surface of the insulating layer 511 are disposed.

The interposer 520 includes a first circuit board portion 521 and a second circuit board portion 522 disposed thereon. In the first circuit board portion 521, a Si substrate, a resin substrate, or a glass substrate is used as a base material 521a, and a via 521b passing therethrough and an electrode 521c electrically connected thereto are disposed. In the second circuit board portion 522, an insulating layer 522a made of an organic material or an inorganic material, wiring 522b and a via 522c disposed in the insulating layer 522a, and an electrode 522d electrically connected thereto and disposed on a surface of the insulating layer 522a are disposed.

The electrode 514 disposed on a surface side of the circuit board 510 facing the interposer 520 and an electrode 521c disposed on a surface side of the interposer 520 facing the circuit board 510 are bonded to each other by the bump 540. The bump 560 for external connection is disposed on the electrode 514 disposed on a surface side of the circuit board 510 opposite to a surface facing the interposer 520. The electrode 522d disposed on a surface side of the interposer 520 facing the semiconductor chip 530 and the electrode 531 disposed on the semiconductor chip 530 are bonded to each other by the bump 550.

The configuration described in any one of the first to third embodiments is applied to at least one of the wiring 512, the via 513, and the electrode 514 in the circuit board 510 and the wiring 522b, the via 522c, and the electrode 522d in the interposer 520 in the electronic device 500. That is, the configuration having, between the conductor portion 20 and the stable compound layer 30 therearound, the isolation layer 40 isolating elements thereof from each other is applied. The configuration described in any one of the first to third embodiments is applied to at least one of the electrode 531 in the semiconductor chip 530, and the wiring and the via (not illustrated) in the semiconductor chip 530. In the wiring 512, the via 513, the electrode 514, the wiring 522b, the via 522c, the electrode 522d, the electrode 531, and the like to which such a configuration is applied, a reaction thereof with an element present at an outside thereof, a reduction in size due to the reaction, and an increase in resistance due to the reduction in size are suppressed. As a result, the electronic device 500 having excellent performance and reliability is achieved.

In the electronic device 500, the interposer 520 in which fine wiring is formed compared with the circuit board 510 is interposed between the circuit board 510 and the semiconductor chips 530. As a result, compared with a case where the semiconductor chips 530 are directly mounted on the circuit board 510, high performance and high functionality of the electronic device 500, and proximity bonding and high density mounting of the semiconductor chips 530 are achieved.

For example, in a case where the semiconductor chip 530 is directly mounted on the circuit board 510, even if fine wiring technology is adopted to improve the performance of the semiconductor chip 530, when the circuit board 510 has a large wiring width, a large wiring pitch, and a large wiring length, it may be impossible to exhibit the performance of the semiconductor chip 530 sufficiently. In a case where a plurality of the semiconductor chips 530 is mounted on one circuit board 510 for high performance and high functionality, when the circuit board 510 has a large wiring width, a large wiring pitch, and a large wiring length, it may be impossible to perform proximity bonding and high density mounting of the semiconductor chips 530. Therefore, as in the electronic device 500, the interposer 520 adopting fine wiring technology is interposed between the circuit board 510 and the semiconductor chips 530. As a result, it is possible to perform proximity bonding and high density mounting of the semiconductor chips 530 on the interposer 520 and to achieve high performance and high functionality of the electronic device 500 by mounting the semiconductor chips 530 on one circuit board 510.

Next, a sixth embodiment will be described.

Electronic components including the conductor portion 20, the isolation layer 40, and the compound layer 30 as described in the first to third embodiments, or electronic devices obtained using such electronic components may be mounted on various electronic apparatuses. For example, such electronic components or electronic devices can be mounted on various electronic apparatuses such as a computer (a personal computer, a supercomputer, a server, or the like), a smartphone, a portable telephone, a tablet terminal, a sensor, a camera, an audio apparatus, a measuring device, an inspection device, and a manufacturing device.

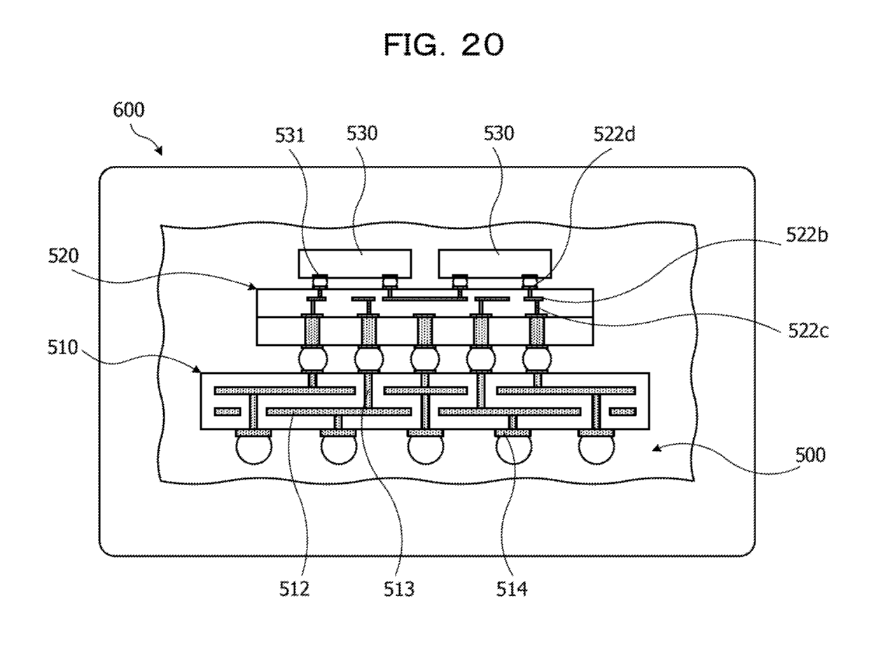

FIG. 20 is an explanatory view of an electronic apparatus according to the sixth embodiment. FIG. 20 schematically illustrates an example of the electronic apparatus.

As illustrated in FIG. 20, for example, the electronic device 500 (FIG. 19) described in the fifth embodiment is mounted (built) in any one of various electronic apparatuses 600.

In the electronic device 500, the wiring 512, the via 513, the electrode 514, the wiring 522b, the via 522c, the electrode 522d, the electrode 531, or the like to which the configuration described in the first to third embodiments is applied, a reaction thereof with an element present at an outside thereof, a reduction in size due to the reaction, and an increase in resistance due to the reduction in size are suppressed. As a result, the electronic device 500 having excellent performance and reliability is achieved. The electronic apparatus 600 having such an electronic device 500 mounted thereon and having excellent performance and reliability is achieved.

Here, the electronic apparatus 600 on which the electronic device 500 described in the fifth embodiment is mounted has been exemplified. In addition, various electronic components such as the electronic components 1A to 1F described in the first to third embodiments, and the circuit board 100, the semiconductor packages 200A, 200B, and 300, and the semiconductor chip 400 described in the fourth embodiment can be mounted on various electronic apparatuses.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic component comprising:
a conductor portion containing a first element;
a compound layer disposed around the conductor portion and containing a second element and a third element which are different from the first element; and
an isolation layer, disposed between the conductor portion and the compound layer and containing a fourth element which is different from the first element, the second element, and the third element, to isolate the first element in the conductor portion from the second element and the third element outside the conductor portion.

2. The electronic component according to claim 1, wherein the isolation layer contains boron as the fourth element.

3. The electronic component according to claim 2, wherein the isolation layer contains the boron, phosphorus, tungsten, or cobalt.

4. The electronic component according to claim 1, wherein the first element is copper, the second element is nickel, and the third element is tin.

5. The electronic component according to claim 1, further comprising an insulating layer covering the compound layer.

6. A method for manufacturing an electronic component, comprising:
forming a laminate including:
a conductor portion containing a first element,
a first metal layer covering the conductor portion and containing a second element and a fourth element which are different from the first element, and
a second metal layer covering the first metal layer and containing a third element which is different from the first element, the second element, and the fourth element;
forming a compound layer containing the second element and the third element by a reaction between the first metal layer and the second metal layer by a heat treatment; and
forming an isolation layer, containing the fourth element segregated between the compound layer and the conductor portion, to isolate the first element in the conductor portion from the second element and the third element outside the conductor portion.

7. The method according to claim 6, further comprising removing the unreacted third element after the heat treatment.

8. An electronic device comprising:
a first electronic component including:
a first conductor portion containing a first element,
a compound layer disposed around the first conductor portion and containing a second element and a third element which are different from the first element, and
an isolation layer, disposed between the first conductor portion and the compound layer and containing a fourth element which is different from the first element, the second element, and the third element, to isolate the first element in the first conductor portion from the second element and the third element outside the first conductor portion; and
a second electronic component including a second conductor portion electrically coupled to the first conductor portion.

9. The electronic device according to claim 8, wherein the isolation layer contains boron as the fourth element.

10. The electronic device according to claim 9, wherein the isolation layer contains the boron, phosphorus, tungsten, or cobalt.

11. The electronic device according to claim 8, wherein the first element is copper, the second element is nickel, and the third element is tin.

12. The electronic device according to claim 8, further comprising an insulating layer covering the compound layer.
